(19) United States
(12) Patent Application Publication
(10) Pub. No.: US 2007/0158632 A1
(43) Pub. Date: Jul. 12, 2007

(54) Method for Fabricating a Pillar-Shaped Phase Change Memory Element

(75) Inventor: ChiaHua Ho, Kaoshing (TW)

Correspondence Address: MACRONIX;C/O HAYNES BEFFEL & WOLFELD LLP, P. O. BOX 366, HALF MOON BAY, CA, 94019, US

(73) Assignee: Macronix International Co., Ltd., Hsinchu (TW)

(21) Appl. No.: 11/462,483

(22) Filed: Aug. 4, 2006

Related U.S. Application Data
(60) Provisional application No. 60/757,341, filed on Jan. 9, 2006.

(51) Int. Cl. H01L 47/00

(52) U.S. Cl. 257/4; 438/900; 257/E29.17

(57) ABSTRACT

A method of fabricating a sub-feature size pillar structure on an integrated circuit. The process first provides a substrate having formed thereon a phase change layer, an electrode layer and a hard-mask layer. Then there is formed a feature-size hard-mask, by lithographically patterning, etching and stripping a photoresist layer, followed by trimming the hard-mask to a selected sub-feature size, wherein the trimming step is highly selective between the electrode and phase change material layers and the hard-mask. The final steps are trimming the electrode and phase change layers to the size of the hard-mask and removing the hard-mask.

### PRIORITY INFORMATION

This application claims the benefit of U.S. Provisional Application No. 60/757,341, entitled “Method for Fabricating a Pillar-Shaped Phase Change Memory Element” filed on 9 Jan. 2006 by ChiaHua Ho.

### BACKGROUND OF THE INVENTION

1. Field of the Invention

The present invention relates to high density memory devices based on phase change based memory materials, including chalcogenide based materials and other materials, and to methods for manufacturing such devices, and most particularly to methods for fabricating such devices having dimensions smaller than the minimum feature size of a manufacturing process.

2. Description of Related Art

Phase change based memory materials are widely used in non-volatile random access memory cells. Such materials, such as chalcogenides and similar materials, can be caused to change phase between an amorphous state and a crystalline state by application of electrical current at levels suitable for implementation in integrated circuits. The generally amorphous state is characterized by higher resistivity than the generally crystalline state, which can be readily sensed to indicate data.

The change from the amorphous to the crystalline state is generally a low current operation. The change from crystalline to amorphous, referred to as reset herein, is generally a higher current operation, which includes a short high current density pulse to melt or breakdown the crystalline structure, after which the phase change material cools quickly, quenching the phase change process, allowing at least a portion of the phase change structure to stabilize in the amorphous state. It is desirable to minimize the magnitude of the reset current used to cause transition of phase change material from crystalline state to amorphous state. The magnitude of the reset current needed for reset can be reduced by reducing the size of the phase change material element in the cell and of the contact area between electrodes and the phase change material, so that higher current densities are achieved with small absolute current values through the phase change material element.

One direction of development has been toward forming small pores in an integrated circuit structure, and using small quantities of programmable resistive material to fill the small pores. Patents illustrating development toward small pores include: Ovshinsky, “Multibit Single Cell Memory Element Having Tapered Contact,” U.S. Pat. No. 5,687,112, issued Nov. 11, 1997; Zahorik et al., “Method of Making Chalogenide [sic] Memory Device,” U.S. Pat. No. 5,789,277, issued Aug. 4, 1998; Doan et al., “Controllable Ovonic Phase-Change Semiconductor Memory Device and Methods of Fabricating the Same,” U.S. Pat. No. 6,150,253, issued Nov. 21, 2000.

Problems have arisen in manufacturing such devices with very small dimensions, and with variations in process that meets tight specifications needed for large-scale memory devices. In particular, the need to produce memory cells with portions thereof having dimensions below 100 nm has encountered the problem that the minimum feature size of a manufacturing process—the smallest size that can be defined by lithographic etching-does not permit the definition and formation of such small features.

The art has recognized this problem but has not presented a solution that allows formation of features in the range of 100 nm and less. For example, U.S. Pat. No. 6,744,088, to Dennison, entitled “Phase Change Memory Device on a Planar Composite Layer” discusses the minimum feature size issue and presents a number of possible solutions, including using shorter-wavelength sources for the lithography, such as x-rays, or phase shift masks, or sidewall spacers, all of which suffice down to approximately 100 nm. No solutions below that level are offered, however.

It is desirable therefore to provide a memory cell structure having small dimensions and low reset currents, and a method for manufacturing such structure that meets tight process variation specifications needed for large-scale memory devices. It is further desirable to provide a manufacturing process and a structure, which are compatible with manufacturing of peripheral circuits on the same integrated circuit.

### SUMMARY OF THE INVENTION

A method of fabricating a sub-feature size pillar structure on an integrated circuit. The process first provides a substrate having formed thereon a phase change layer, an electrode layer and a hard-mask layer. Then there is formed a feature-size hard-mask, by lithographically patterning, etching and stripping a photoresist layer, followed by trimming the hard-mask to a selected sub-feature size, wherein the trimming step is highly selective between the electrode and phase change material layers and the hard-mask. The final steps are trimming the electrode and phase change layers to the size of the hard-mask and removing the hard-mask.

### BRIEF DESCRIPTION OF THE DRAWINGS

FIG. 1 illustrates the pillar-shaped random access memory element of the present invention.

FIG. 2 illustrates an initial step in the fabrication of the pillar-shaped random access memory element of the present invention.

FIG. 3 illustrates a further step in the fabrication of the pillar-shaped random access memory element of the present invention.

FIG. 4 illustrates a further step in the fabrication of the pillar-shaped random access memory element of the present invention.

FIG. 5 illustrates a further step in the fabrication of the pillar-shaped random access memory element of the present invention.

### DETAILED DESCRIPTION

The following detailed description is made with reference to the figures. Preferred embodiments are described to illustrate the present invention, not to limit its scope, which is defined by the claims. Those of ordinary skill in the art will recognize a variety of equivalent variations on the description that follows.

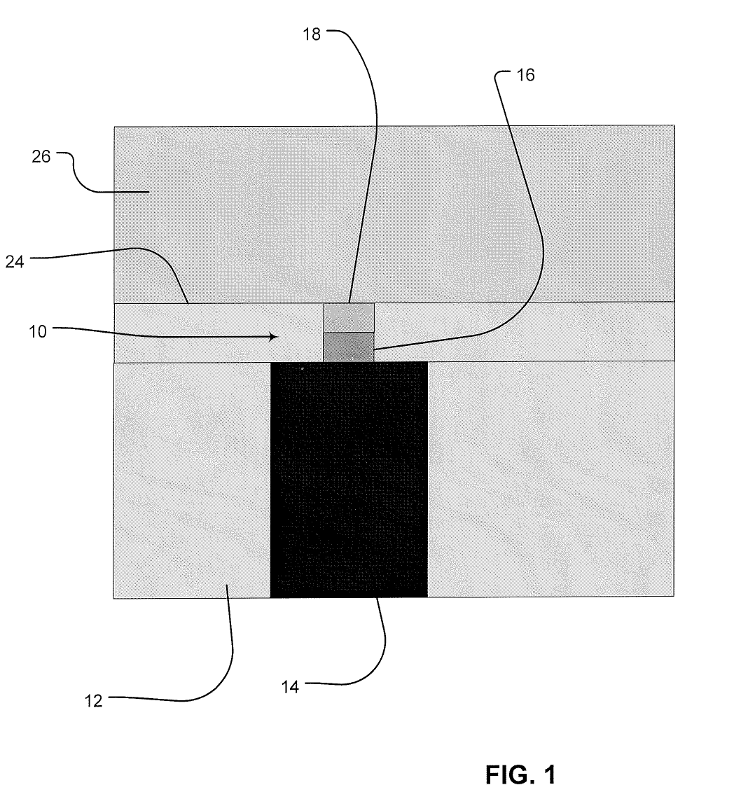

FIG. 1 depicts the pillar structure 10 of the present invention. The pillar structure is carried on a substrate 12, which typically is formed from silicon dioxide or other structure known in the art, with a contact plug 14, preferably formed from a refractory metal such as tungsten and copper, extending through the substrate to make contact with associated circuitry (not shown). Other refractory metals that could be employed include Ti, Mo, Al, Ta, Cu, Pt, Ir, La, Ni, and Ru.

The pillar itself is a relatively narrow structure having two layers—a phase change material layer 16 and an electrode layer 18. The electrode layer is a film of a material having good electrical conductivity, good adhesion characteristics regarding the phase change material, and a material that provides a good diffusion barrier for the phase change material. It is preferred to employ titanium nitride for this layer, with other possibilities being Ti, W, Ta, TaN, TiW and similar materials, such as and some electrically conductive oxides with low thermal conductivity, such as LiNbO3, LaSrMnO3, ITO, etc. This layer has a thickness of from about 10 to 200 nm, and in one embodiment 75 nm is preferred. The phase change layer has a thickness of about 10 to 100 nm, and in one embodiment 50 nm is preferred.

With regard to directional descriptions herein, the orientation of the drawings establish their respective frames of reference, with “up,” “down,” “left” and “right” referring to directions shown on the respective drawings. Similarly, “thickness” refers to a vertical dimension and “width” to the horizontal. These directions have no application to orientation of the circuits in operation or otherwise, as will be understood by those in the art.

The phase change layer 16 is composed of phase change-based memory material, preferably chalcogenide based. Chalcogens include any of the four elements oxygen (O), sulfur (S), selenium (Se), and tellurium (Te), forming part of group VI of the periodic table. Chalcogenides comprise compounds of a chalcogen with a more electropositive element or radical. Chalcogenide alloys comprise combinations of chalcogenides with other materials such as transition metals. A chalcogenide alloy usually contains one or more elements from column six of the periodic table of elements, such as germanium (Ge) and tin (Sn). Often, chalcogenide alloys include combinations including one or more of antimony (Sb), gallium (Ga), indium (In), and silver (Ag). Many phase change based memory materials have been described in technical literature, including alloys of: Ga/Sb, In/Sb, In/Se, Sb/Te, Ge/Te, Ge/Sb/Te, In/Sb/Te, Ga/Se/Te, Sn/Sb/Te, In/Sb/Ge, Ag/In/Sb/Te, Ge/Sn/Sb/Te, Ge/Sb/Se/Te and Te/Ge/Sb/S. In the family of Ge/Sb/Te alloys, a wide range of alloy compositions may be workable. The compositions can be characterized as TeaGebSb100−(a+b). One researcher has described the most useful alloys as having an average concentration of Te in the deposited materials well below 70%, typically below about 60% and ranged in general from as low as about 23% up to about 58% Te and most preferably about 48% to 58% Tc. Concentrations of Ge were above about 5% and ranged from a low of about 8% to about 30% average in the material, remaining generally below 50%. Most preferably, concentrations of Ge ranged from about 8% to about 40%. The remainder of the principal constituent elements in this composition was Sb. These percentages are atomic percentages that total 100% of the atoms of the constituent elements. (Ovshinsky '112 patent, cols. 10-11.) Particular alloys evaluated by another researcher include Ge2Sb2Te5, GeSb2Te4 and GeSb4Te7. (Noboru Yamada, “Potential of Ge—Sb—Te Phase-Change Optical Disks for High-Data-Rate Recording”, SPIE v. 3109, pp. 28-37(1997).) More generally, a transition metal such as chromium (Cr), iron (Fe), nickel (Ni), niobium (Nb), palladium (Pd), platinum (Pt) and mixtures or alloys thereof may be combined with Ge/Sb/Te to form a phase change alloy that has programmable resistive properties. Specific examples of memory materials that may be useful are given in Ovshinsky '112 at columns 11-13, which examples are hereby incorporated by reference.

Phase change alloys are capable of being switched between a first structural state in which the material is in a generally amorphous solid phase, and a second structural state in which the material is in a generally crystalline solid phase in its local order in the active channel region of the cell. These alloys are at least bistable. The term amorphous is used to refer to a relatively less ordered structure, more disordered than a single crystal, which has the detectable characteristics such as higher electrical resistivity than the crystalline phase. The term crystalline is used to refer to a relatively more ordered structure, more ordered than in an amorphous structure, which has detectable characteristics such as lower electrical resistivity than the amorphous phase. Typically, phase change materials may be electrically switched between different detectable states of local order across the spectrum between completely amorphous and completely crystalline states. Other material characteristics affected by the change between amorphous and crystalline phases include atomic order, free electron density and activation energy. The material may be switched either into different solid phases or into mixtures of two or more solid phases, providing a gray scale between completely amorphous and completely crystalline states. The electrical properties in the material may vary accordingly.

Phase change alloys can be changed from one phase state to another by application of electrical pulses. It has been observed that a shorter, higher amplitude pulse tends to change the phase change material to a generally amorphous state. A longer, lower amplitude pulse tends to change the phase change material to a generally crystalline state. The energy in a shorter, higher amplitude pulse is high enough to allow for bonds of the crystalline structure to be broken and short enough to prevent the atoms from realigning into a crystalline state. Appropriate profiles for pulses can be determined, without undue experimentation, specifically adapted to a particular phase change alloy. In following sections of the disclosure, the phase change material is referred to as GST, and it will be understood that other types of phase change materials can be used. A material useful for implementation of a PCRAM described herein is Ge₂Sb₂Te₅.

Other programmable resistive memory materials may be used in other embodiments of the invention, including N₂ doped GST, GeₓSb_{y}, or other material that uses different crystal phase changes to determine resistance; PrₓCa_{y}MnO₃, PrSrMnO, ZrOₓ, or other material that uses an electrical pulse to change the resistance state; TCNQ, PCBM, TCNQ-PCBM, Cu-TCNQ, Ag-TCNQ, C60-TCNQ, TCNQ doped with other metal, or any other polymer material that has bistable or multi-stable resistance state controlled by an electrical pulse.

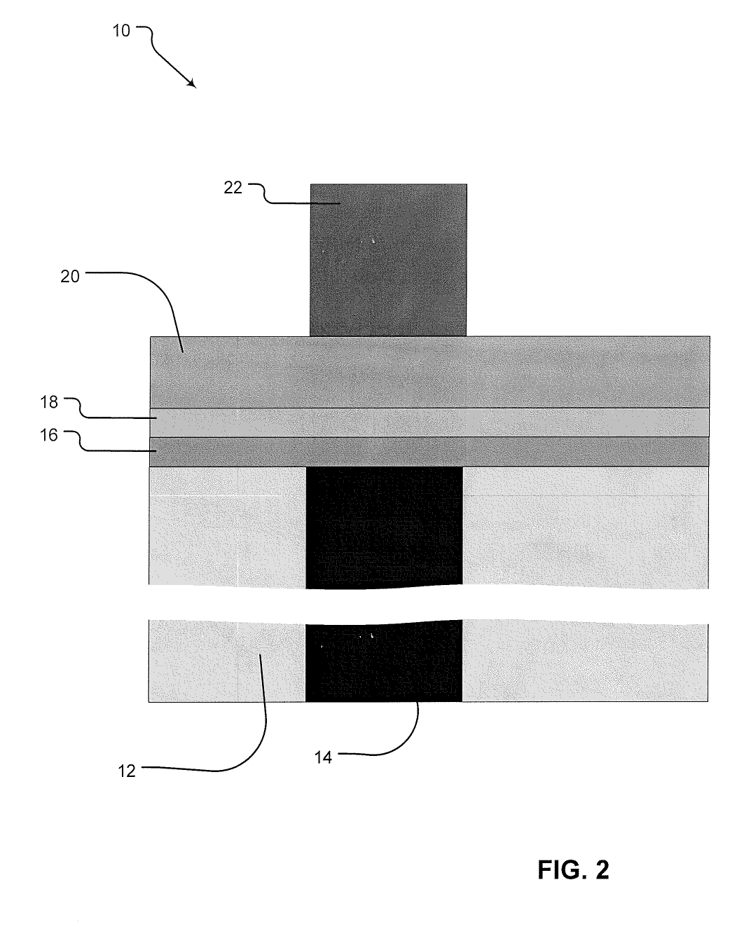

A starting point for fabrication of the device of the present invention is seen in FIG. 2, showing a point in the fabrication process following deposition of phase change layer 16 and electrode layer 18 atop substrate 12. Those deposition processes are well-understood, and they result in uniform film layers of their respective materials across the surface of the substrate, at the thickness levels noted above.

Conventional technique would call for a lithography process next, but such processes do not suffice to produce circuit features at a size below the minimum feature size of the lithography process in use. Here, a hard-mask layer 20 is deposited over electrode layer 18. A hard-mask is formed of material having greater resistance to etching processes than exhibited by conventional photoresist materials. Among the materials known in the art as useful in hard-mask applications, three embodiments are believed particularly suited to the process of the present invention. A first embodiment would employ silicon oxide, a second embodiment silicon nitride and a third tungsten. Those in the art will appreciate the fact that other materials could be used. Here, the following discussion will note process options for each of the three embodiments mentioned above.

Deposition techniques are adapted to the materials chosen in each embodiment. Silicon oxide and nitride layers can be deposited using high-density plasma HDP chemical vapor deposition CVD. A tungsten layer is preferably deposited employing a known metallization process, such as physical vapor deposition (PVD) or a variant thereof. For all three embodiments, the hard-mask layer can be from about 50 to about 300 nm thick.

The hard-mask layer is patterned employing a conventional lithographic process, as reflected by the presence of photomask 22 atop the hard-mask layer. The photomask is produced by the known process of depositing a layer of photoresist material, exposing the material to radiation (light or UV) through a mask or reticle and stripping the unwanted portion of material to leave the mask. The mask dimension is limited by the minimum feature size of the process, which in the process depicted here is about 150 nm. It should be noted that apart from noting the problems posed by the minimum feature size, no further treatment of that issue will be made herein. The photomask 22 is preferably formed at about the minimum feature size permitted by the manufacturing process.

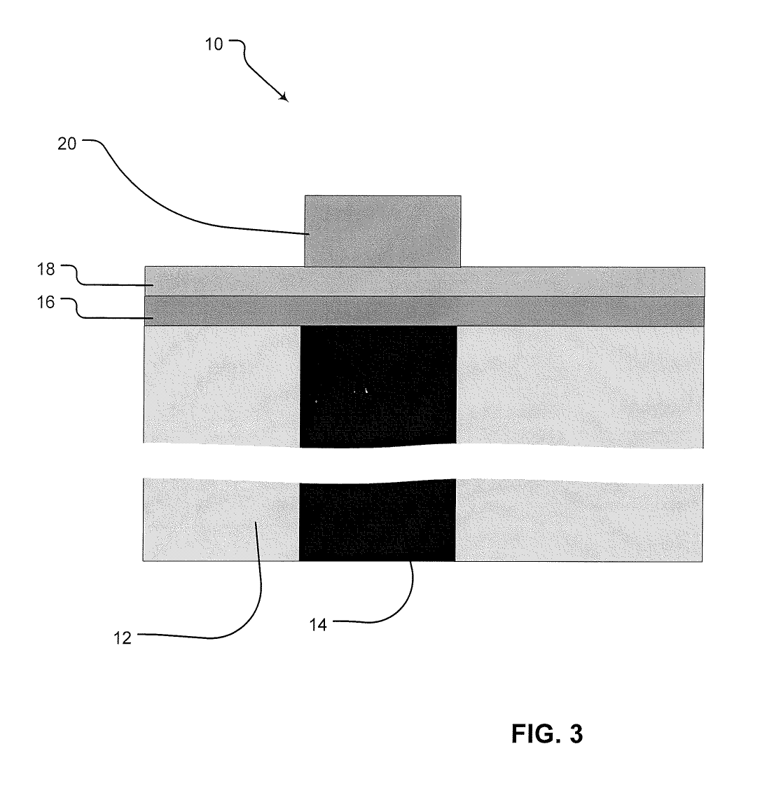

FIG. 3 shows the results of the hard-mask etching step. Generally, the hard-mask has been removed in all areas exposed by the photoresist (see FIG. 2), down to the top of the electrode layer 18. The specific etching method should be tailored to the makeup of the hard-mask, and in addition the need for the etchant to exhibit selectivity between the hard-mask material and the electrode should be taken into account. Thus, different etching processes are used for each hard-mask embodiment. For the embodiment using a silicon oxide hard-mask, it is preferred to employ reactive ion etching (RIE), with CF₄ etchant. Other suitable chemistries include CHF₃, Ar, C₄F₈, O₂ or other chemistries as known in the art. For the embodiment using a silicon nitride hard-mask, it is also preferred to employ RIE, with CF₄ etchant. Other suitable chemistries include CH₃F, Ar, CHF₃, O₂ or other chemistries as known in the art. For the embodiment using a tungsten hard-mask, it is also preferred to employ RIE, with SF₆ etchant. Other suitable chemistries include Ar, N₂, O₂ or other chemistries as known in the art.

After etching the hard-mask, the photoresist is stripped. It is preferred to strip the photoresist, rather than leaving it in place, as the polymer material of the photoresist can be degraded in subsequent steps, producing organic waste material that can be difficult to deal with. The preferred stripping method for all three embodiments employs O₂ plasma, which can be followed by a wet-strip using a suitable solvent, such as EKC265, to assist performance. These processes and their employment are well known in the art.

At this point, the remaining hard-mask material is about 150 nm in width, and it is required to trim the critical dimension of the hard-mask (here, the width) to about 50 nm. The approach of the present invention is to utilize an etching process to trim the width of the hard-mask 20. Such a process must be capable of precise control through timing, as well as highly selective between the electrode layer and the hard-mask.

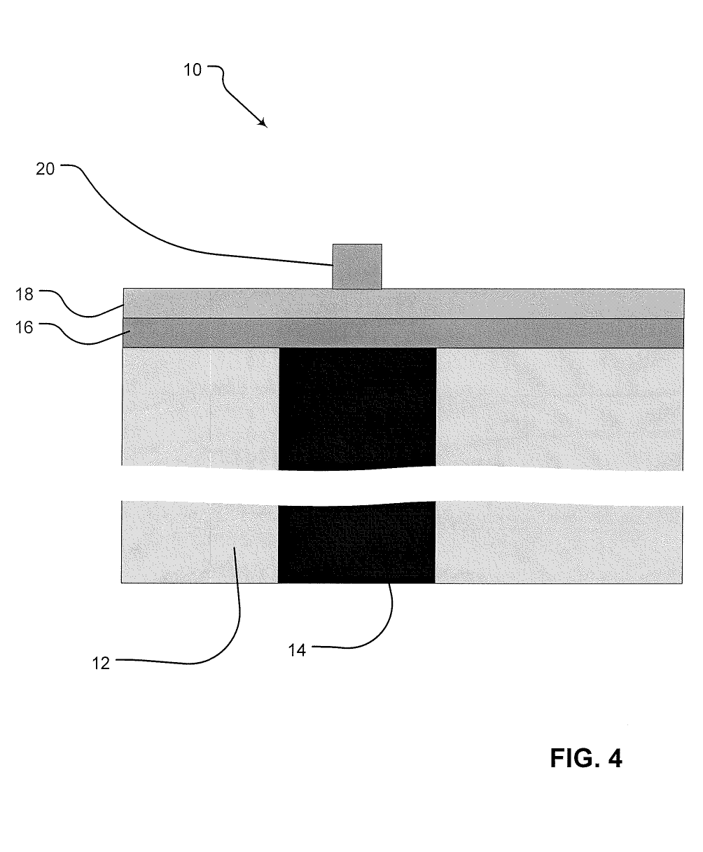

FIG. 4 shows the results of the hard-mask trim step. As can be seen, hard-mask 20 is reduced in size by about two-thirds, or in this instance, to about 50 nm. As with the previous etching step, the process for each hard-mask embodiment differs. A common factor, however, is that each of the processes call for wet etching, a process that offers superior control and selectivity. For the silicon oxide hard-mask, the process employs dilute HF or buffered HF. The silicon nitride embodiment uses hot phosphoric acid as an etchant, and the tungsten embodiment utilizes H₂O₂, together with a suitable solvent, for that purpose. Wet etching is a process well known in the art, and the use of such processes here proceeds according to principles understood in the art.

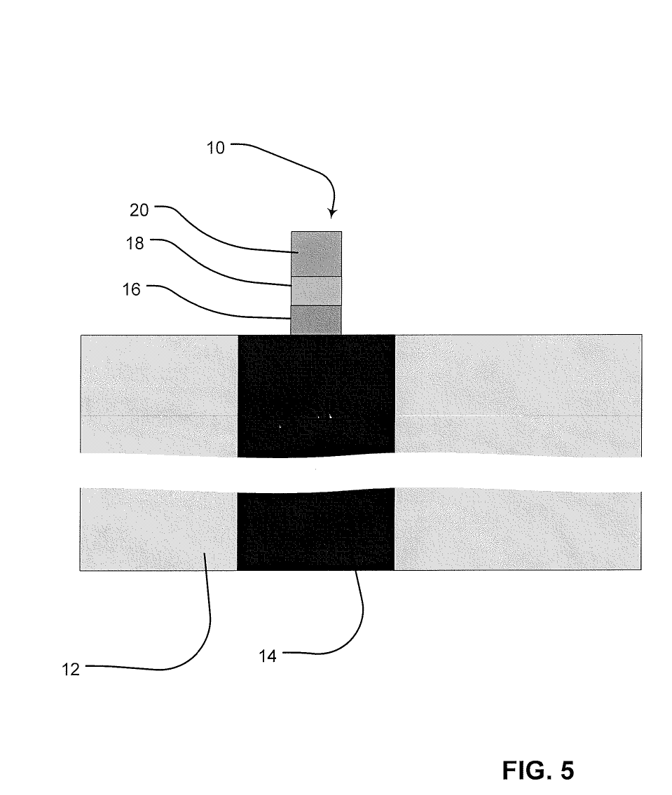

Once the hard-mask has been trimmed to the desired size, it can perform a mask function in trimming the electrode and phase control layers to the same size. FIG. 5 depicts the results of that portion of the trimming operation. As can be seen, the electrode layer 18 and phase control layer 16 are cut to the width of hard-mask 20, leaving a relatively narrow, pillar-like structure in contact with plug 14.

The etching process for this step should meet several criteria. First, the process should be anisotropic, as it needs to remove the electrode and phase change layers without undercutting the hard-mask. It should also have good selectivity between the electrode and phase change materials and hard-mask material, as well as the underlying substrate and plug materials.

One embodiment of the invention utilizes RIE etching, with Cl₂ as the preferred etchant. Alternative embodiments could employ BCl₃, Ar, HBr, CHF₃, or O₂ as etchants, either individually or in combination. It is known in the art to identify a family of suitable etchants and to combine them to achieve optimum results for a particular application. Such combinations rely on the specific task at hand, but the process for selecting and testing such combinations is well known in the art.

Rather than a timed process, this etching is complete when removing the desired portion of the phase change layer, which allows the use of optical emission end-point sensing to detect the change in etch by-products that accompanies the complete removal of the phase change layer and arrival at the substrate. Such instruments perform spectrographic analysis of the plasma and identify, for example, when silicon oxide appears in the plasma, indicating arrival at the substrate.

An alternative to the one-step process described above is a two-step etching process for removing the phase change and electrode layers. Here, rather than removing those two layers in a single step, separate sub-steps are employed, either with the same or different etch chemistries. Here, both steps employ RIE etching, with Cl₂ as the preferred etchant. Alternative embodiments could employ BCl₃, Ar, HBr, CHF₃, or O₂ as etchants, either individually or in combination. The first step employs an end-point sensing system keyed to arrival at the phase change layer to trigger the stop signal. The second step cutoff is triggered on arrival at the silicon oxide substrate.

The finished product is seen in the structure of FIG. 1. That result is achieved by the following steps from FIG. 5. First, the hard-mask is stripped away, leaving the phase change element formed of phase change layer 16 and electrode layer 18. A layer of dielectric material 24 is deposited over and around the phase change element, and a bit-line electrode structure is preferably formed over the same, providing contact between the bit-line and the electrode layer. The dielectric layer is preferably silicon oxide or some other low-k material, deposited in a high-density plasma (HDP) or chemical vapor deposition (CVD) process, or using spin-coating or another known process. One embodiment proceeds by depositing the dielectric layer to a thickness of 200-1000 nm, with 300 nm being preferred. A chemical-mechanical polishing (CMP) process is used to planarize the dielectric surface, followed by a bit-line lithographic process to form a bit-line trench in the dielectric, extending to the level of the electrode layer. A suitable contact metal, such as Cu, is deposited in the trench, and another CMP process planarizes the resulting surface.

It should be noted that the generally pillar-like shape of the phase change element is an important consequence of the process disclosed above. Generally, phase change elements have been tabular in shape, but here the process of the present invention is able to produce an element that has a small volume, which minimizes the current required to effect the phase change. That in turn minimizes the heat generated in the cell, an important characteristic of a device in which millions of cells will be arrayed.

Those in the art will understand that other alternative, beyond those set out above, could be employed in practicing the techniques set out herein, without departing from the spirit of the invention. The invention itself is defined solely by the claims appended below.

I claim as follows:

1. A method of fabricating a sub-feature size pillar structure on an integrated circuit, comprising the steps of:
providing a substrate having formed thereon a phase change layer, an electrode layer and a hard-mask layer;
forming a feature-size hard-mask, by lithographically patterning, etching and stripping a photoresist layer;
trimming the hard-mask to a selected sub-feature size, wherein the trimming step is highly selective between the electrode and phase change material layers and the hard-mask;
trimming the electrode and phase change layers to the size of the hard-mask; and
removing the hard-mask.

2. The method of claim 1, wherein the hard-mask has a thickness of between about 50 and 300 nm.

3. The method of claim 1, wherein the hard-mask is formed of silicon oxide.

4. The method of claim 1, wherein the hard-mask is formed of silicon nitride.

5. The method of claim 1, wherein the hard-mask is formed of tungsten.

6. The method of claim 1, wherein
the forming step includes lithographic patterning at about the minimum feature size of the process; and
the trimming step trims the hard-mask to a size less than the minimum feature size of the process.

7. The method of claim 1, wherein the trimming step trims the hard-mask to a size of about 50 nm.

8. The method of claim 1, wherein the hard-mask trimming step includes dry etching the hard-mask.

9. The method of claim 8, wherein the dry etching includes reactive ion etching.

10. The method of claim 1, wherein the electrode and phase change layer trimming step includes wet etching the electrode and phase change layers.

11. A method of fabricating a sub-feature size pillar structure on an integrated circuit, comprising the steps of:
providing a substrate having formed thereon a film phase change layer, a film electrode layer and a hard-mask layer, wherein
the hard-mask has a thickness between about 50 and 300 nm;
the hard-mask is formed from a material selected from among the group consisting of silicon oxide, silicon nitride and tungsten; and
the phase change layer has a thickness between about 10 to 100 nm.
forming a feature-size hard-mask, by lithographically patterning, etching and stripping a photoresist layer, wherein the patterning step forms a lithographic pattern at about the minimum feature size of the manufacturing process;
trimming the hard-mask to a selected sub-feature size, wherein
the trimming step is selective between the electrode and phase change material layers and the hard-mask; and
the hard mask is trimmed to a size of about 50 nm;
trimming the electrode and phase change layers to the size of the hard-mask, employing a dry etching in a reactive ion etching tool; and
removing the hard-mask.

12. A memory cell, comprising
electrodes, carried in a substrate and in communication with a computer apparatus;
a phase-change element having a generally square cross-section with a critical dimension of about 50 nm and a thickness of about 50 nm, including a barrier electrode member in contact with one of the electrodes;
a phase change member in contact with the barrier electrode member and the other electrode, wherein the phase change member is formed of a material have at least two solid phases.

13. The device of claim 12, wherein the memory material comprises a combination of Ge, Sb, and Te.

14. The memory device of claim 12, wherein the phase-change cell comprises a combination of two or more materials from the group of Ge, Sb, Te, Se, In, Ti, Ga, Bi, Sn, Cu, Pd, Pb, Ag, S, and Au.

15. The memory device of claim 12, wherein the critical dimension is transverse to the path of current flow between the electrodes.

16. The memory device of claim 11, wherein the hard mask trimming includes a wet etching process.

17. The memory device of claim 11, wherein the hard-mask trimming includes etching in a reactive ion etching tool.
